(19) United States
(12) Patent Application Publication
(10) Pub. No.: US 2026/0275163 A1
(43) Pub. Date: Sep. 17, 2026

(54) ALUMINUM-DOPED SILICA-BASED SLURRY FOR SELECTIVE POLISHING OF CARBON-BASED FILMS

(71) Applicant: ENTEGRIS, INC., Billerica, MA (US)

(72) Inventors: Brian Reiss, Woodridge, IL (US); Yuqing Yang, Naperville, IL (US); Alex Villani-Gale, Chicago, IL (US); Elliot Knapton, Aurora, IL (US); Elena C. Montoto-Blanco, Chicago, IL (US); Hawa Keita, Aurora, IL (US); Tamil Sakthivel, Aurora, IL (US)

(21) Appl. No.: 19/558,705

(22) Filed: Mar. 6, 2026

Related U.S. Application Data
(60) Provisional application No. 63/771,277, filed on Mar. 13, 2025.

(51) Int. Cl. C09G 1/02; B24B 37/04; C09K 3/14; H10P 52/40

(52) U.S. Cl. CPC C09G 1/02; B24B 37/044; C09K 3/1409; H10P 52/407

(57) ABSTRACT

The invention provides a chemical-mechanical polishing composition comprising: (a) a silica abrasive, (b) aluminum ions, and (c) water, wherein (i) the aluminum ions are present in the polishing composition as an aluminum salt and/or (ii) the silica abrasive is doped with the aluminum ions, and wherein the polishing composition has a pH of about 1 to about 4. The invention also provides a method of chemically-mechanically polishing a substrate, especially a substrate comprising a carbon-based film, using said composition.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

A polishing composition can be characterized according to its polishing rate (i.e., removal rate) and its planarization efficiency. The polishing rate refers to the rate of removal of a material from the surface of the substrate and is usually expressed in terms of units of length (thickness) per unit of time (e.g., Angstroms (Å) per minute). Planarization efficiency relates to step height reduction versus amount of material removed from the substrate. Specifically, a polishing surface, e.g., a polishing pad, first contacts the “high points” of the surface and must remove material in order to form a planar surface. A process that results in achieving a planar surface with less removal of material is considered to be more efficient than a process requiring removal of more material to achieve planarity.

As the size of integrated circuits is reduced and the number of integrated circuits on a chip increases, the components that make up the circuits must be positioned closer together in order to comply with the limited space available on a typical chip. Effective isolation between circuits is important for ensuring optimum semiconductor performance. To that end, shallow trenches are etched into the semiconductor substrate and filled with insulating material to isolate active regions of the integrated circuit. More specifically, shallow trench isolation (STI) is a process in which a silicon nitride layer or a titanium nitride layer is formed on a silicon substrate, shallow trenches are formed via etching or photolithography, and a dielectric layer is deposited to fill the trenches. Due to variation in the depth of trenches formed in this manner, it is typically necessary to deposit an excess of dielectric material on top of the substrate to ensure complete filling of all trenches. The dielectric material (e.g., carbon-based film) conforms to the underlying topography of the substrate. The excess dielectric material is typically removed by a CMP process, which additionally provides a planar surface for further processing.

Carbon-based films have recently emerged as hard mask materials for faster switching semiconductor applications such as, for example, 3D-NAND flash memory. Often the rate of removal of the carbon-based films (e.g., amorphous carbon and spin-on carbon) can be rate-limiting for the dielectric polishing step in STI processes due to strong sp² and sp³ carbon-carbon bonding, and therefore high removal rates of the carbon-based film are desired to increase device throughput. However, if the blanket removal rate is too rapid, overpolishing of oxide in exposed trenches results in trench erosion and increased device defectivity.

Conventional methods for removing carbon-based films include using polishing compositions containing strong chemical oxidizers such as, for example, potassium permanganate and cerium ammonium nitrate. However, these strong chemical oxidizers can pose handling hazards and/or produce undesired residues on the polishing surface.

Thus, a need remains for compositions and methods for chemical-mechanical polishing of carbon-based films, which will provide useful removal rates while also providing reduced undesirable residue on the polishing surface. The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) a silica abrasive, (b) aluminum ions, and (c) water, wherein (i) the aluminum ions are present in the polishing composition as an aluminum salt and/or (ii) the silica abrasive is doped with the aluminum ions, and wherein the polishing composition has a pH of about 1 to about 4.

The invention further provides a method of chemically-mechanically polishing a substrate comprising: (i) providing a substrate, (ii) providing a polishing pad, (iii) providing a chemical-mechanical polishing composition comprising: (a) a silica abrasive, (b) aluminum ions, and (c) water, wherein (i) the aluminum ions are present in the polishing composition as an aluminum salt and/or (ii) the silica abrasive is doped with the aluminum ions, and wherein the polishing composition has a pH of about 1 to about 4, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### DETAILED DESCRIPTION OF THE INVENTION

The invention provides a chemical-mechanical polishing composition comprising: (a) a silica abrasive, (b) aluminum ions, and (c) water, wherein (i) the aluminum ions are present in the polishing composition as an aluminum salt and/or (ii) the silica abrasive is doped with the aluminum ions, and wherein the polishing composition has a pH of about 1 to about 4.

The chemical-mechanical polishing composition comprises a silica abrasive. As used herein, the terms “silica abrasive,” “silica abrasive particle,” “silica particle,” and “abrasive particle” can be used interchangeably, and can refer to any silica particle. The silica particle can be modified (e.g., surface modified) or unmodified, and has a negative native zeta potential, a positive native zeta potential, or an approximately neutral native zeta potential. As used herein, the phrase “native zeta potential” refers to the zeta potential of the silica abrasive prior to adding the silica abrasive to the polishing composition. For example, the native zeta potential can refer to the zeta potential of a silica abrasive prior to adding the silica abrasive to the polishing composition as measured in a storage dispersion or an aqueous dispersion. A skilled artisan will be able to determine whether the silica abrasive, prior to adding the silica abrasive to the polishing composition, has a negative native zeta potential or a positive native zeta potential.

The charge on dispersed particles such as a silica abrasive is commonly referred to as the zeta potential (or the electrokinetic potential). The zeta potential of a particle refers to the electrical potential difference between the electrical charge of the ions surrounding the particle and the electrical charge of the bulk solution of the composition in which it is measured (e.g., the liquid carrier and any other components dissolved therein). The zeta potential is typically dependent on the pH of the aqueous medium. For a given polishing composition, the isoelectric point of the particles is defined as the pH at which the zeta potential is zero. As the pH is increased or decreased away from the isoelectric point, the surface charge (and hence the zeta potential) is correspondingly decreased or increased (to negative or positive zeta potential values). The native zeta potential and the zeta potential of the polishing composition may be obtained using the Model DT-1202 Acoustic and Electro-acoustic spectrometer available from Dispersion Technologies, Inc. (Bedford Hills, N.Y.) or with electrophoretic light scattering using a Malvern Zetasizer available from Malvern Panalytical (Malvern, United Kingdom).

In some embodiments, the silica abrasive has a negative native zeta potential. As used herein, the phrase “negative native zeta potential” refers to a silica abrasive that exhibits a negative surface charge when measured in a neutral aqueous solution prior to addition to the polishing composition. In some embodiments, the silica abrasive has a native zeta potential of less than 0 mV when measured in a neutral aqueous solution prior to addition to the polishing composition, i.e., the silica abrasive has a negative native zeta potential when measured in a neutral aqueous solution prior to addition to the polishing composition. For example, the silica abrasive can have a native zeta potential of −10 mV or less, a native zeta potential of −20 mV or less, a native zeta potential of −30 mV or less, or a native zeta potential of −40 mV or less. In some embodiments, the silica abrasive has a native negative zeta potential of from about 0 mV to about −60 mV, e.g., from about −10 mV to about −60 mV, from about −10 mV to about −50 mV, from about −10 mV to about −40 mV, from about −20 mV to about −60 mV, from about −20 mV to about −50 mV, from about −20 mV to about −40 mV, from about −30 mV to about −40 mV, from about −20 mV to about −30 mV, from about −30 mV to about −60 mV, from about −30 mV to about −50 mV, or from about −30 mV to about −40 mV.

Silica particles (e.g., colloidal silica particles) and charged silica particles (e.g., colloidal silica particles) can be prepared by various methods, some examples of which are commercially used and known. Useful silica particles include precipitated or condensation-polymerized silica, which may be prepared using known methods, such as by methods referred to as the “sol gel” method or by silicate ion-exchange. Condensation-polymerized silica particles are often prepared by condensing Si(OH)₄ to form substantially spherical (e.g., spherical, ovular, or oblong) particles. The precursor Si(OH)₄ may be obtained, for example, by hydrolysis of high purity alkoxysilanes, or by acidification of aqueous silicate solutions. U.S. Pat. No. 5,230,833 describes a method for preparing colloidal silica particles in solution.

In some embodiments, the silica abrasive is colloidal silica. As known to one of ordinary skill in the art, colloidal silicas are suspensions of fine amorphous, nonporous and typically spherical particles in a liquid phase. The colloidal silica can take the form of condensation-polymerized or precipitated silica particles. In some embodiments, the silica is in the form of wet-process type silica particles. The particles, e.g., colloidal silica, can have any suitable average size (i.e., average particle diameter). If the average abrasive particle size is too small, the polishing composition may not exhibit sufficient removal rate. In contrast, if the average abrasive particle size is too large, the polishing composition may exhibit undesirable polishing performance such as, for example, poor substrate defectivity.

Accordingly, the silica abrasive can have an average particle size of about 10 nm or more, for example, about 15 nm or more, about 20 nm or more, about 25 nm or more, about 30 nm or more, about 35 nm or more, about 40 nm or more, about 45 nm or more, about 50 nm or more, about 60 nm or more, about 70 nm or more, about 80 nm or more, about 90 nm or more, or about 100 nm or more. Alternatively, or in addition, the silica abrasive can have an average particle size of about 200 nm or less, for example, about 175 nm or less, about 150 nm or less, about 125 nm or less, about 110 nm or less, about 100 nm or less, about 90 nm or less, about 80 nm or less, about 75 nm or less, about 60 nm or less, about 50 nm or less, or about 40 nm or less. Thus, the silica abrasive can have an average particle size bounded by any two of the aforementioned endpoints.

For example, the silica abrasive can have an average particle size of about 10 nm to about 200 nm, about 20 nm to about 200 nm, about 20 nm to about 175 nm, about 20 nm to about 150 nm, about 20 nm to about 125 nm, about 20 nm to about 110 nm, about 20 nm to about 100 nm, about 25 nm to about 125 nm, about 25 nm to about 110 nm, about 25 nm to about 100 nm, about 30 nm to about 100 nm, about 30 nm to about 75 nm, about 30 nm to about 40 nm, about 40 nm to about 100 nm, about 40 nm to about 75 nm, about 40 nm to about 60 nm, about 50 nm to about 150 nm, about 50 nm to about 125 nm, about 50 nm to about 110 nm, about 50 nm to about 100 nm, about 80 nm to about 150 nm, about 80 nm to about 125 nm, about 80 nm to about 110 nm, about 80 nm to about 100 nm, about 90 nm to about 150 nm, about 90 nm to about 125 nm, about 90 nm to about 110 nm, about 90 nm to about 100 nm, about 100 nm to about 150 nm, or about 100 nm to about 125 nm. In some embodiments, the silica abrasive has an average particle size of about 40 nm to about 100 nm. In certain embodiments, the silica abrasive has an average particle size of about 40 nm to about 80 nm. For non-spherical silica abrasive particles, the size of the particle is the diameter of the smallest sphere that encompasses the particle. The particle size of the abrasive can be measured using any suitable technique, for example, using laser diffraction techniques. Suitable particle size measurement instruments are available from e.g., Malvern Instruments (Malvern, UK).

The silica abrasive preferably are colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]≤0.5). More preferably, the value of [B]−[T]/[C] is less than or equal to 0.3, and most preferably is less than or equal to 0.1.

The silica abrasive can be present in the polishing composition in any suitable amount. If the polishing composition of the invention comprises too little abrasive, the composition may not exhibit sufficient removal rate. In contrast, if the polishing composition comprises too much abrasive, then the polishing composition may exhibit undesirable polishing performance and/or may not be cost effective and/or may lack stability. The polishing composition can comprise about 10 wt. % or less of the silica abrasive, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the silica abrasive. Alternatively, or in addition, the polishing composition can comprise about 0.001 wt. % or more of the silica abrasive, for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of silica abrasive. Thus, the polishing composition can comprise silica abrasive in an amount bounded by any two of the aforementioned endpoints, as appropriate.

For example, in some embodiments, the silica abrasive can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the silica abrasive. In certain embodiments, the polishing composition comprises about 0.05 wt. % to about 5 wt. % of the silica abrasive.

The chemical-mechanical polishing composition comprises aluminum ions, wherein (i) the aluminum ions are present in the polishing composition as an aluminum salt and/or (ii) the silica abrasive is doped with the aluminum ions.

In some embodiments, the silica abrasive (e.g., colloidal silica particles) is doped with aluminum ions. For example, the polishing composition can comprise silica particles (e.g., negatively charged colloidal silica particles), as described above, that are surface-modified with aluminum ions (i.e., Al(III)). The silica particles (e.g., negatively charged colloidal silica particles) can be prepared in the absence of an aluminum ion, such that the silica particles, prior to surface modification with aluminum ions, are free or substantially free of metal ions. In certain embodiments, the silica particles are prepared by condensation-polymerization of Si(OH)₄, as described above.

The silica particles (e.g., negatively charged colloidal silica particles) can have a surface hydroxyl group density of about 1.5 hydroxyls per nm² of the surface area of the particles or more, for example, about 1.6 hydroxyls per nm² or more, about 1.7 hydroxyls per nm² or more, about 1.8 hydroxyls per nm² or more, about 1.9 hydroxyls per nm² or more, about 2.0 hydroxyls per nm² or more, about 2.2 hydroxyls per nm² or more, about 2.4 hydroxyls per nm² or more, about 2.6 hydroxyls per nm² or more, about 2.8 hydroxyls per nm² or more, about 3 hydroxyls per nm² or more, about 4 hydroxyls per nm² or more, or about 5 hydroxyls per nm² or more. Alternatively, or in addition, the silica (e.g., negatively charged colloidal silica particles) particles can have a surface hydroxyl group density of about 8 hydroxyls per nm² of the surface area of the particles or less, for example, about 7.5 hydroxyls per nm² or less, about 7 hydroxyls per nm² or less, about 6.5 hydroxyls per nm² or less, about 6 hydroxyls per nm² or less, about 5.5 hydroxyls per nm² or less, or about 5 hydroxyls per nm² or less.

Thus, the silica particles (e.g., negatively charged colloidal silica particles) can have a surface hydroxyl group density bounded by any two of the aforementioned endpoints. For example, the silica particles (e.g., negatively charged colloidal silica particles) can have a surface hydroxyl group density of from about 1.5 hydroxyls per nm² to about 8 hydroxyls per nm² of the surface area of the particles, about 1.6 hydroxyls per nm² to about 8 hydroxyls per nm², about 1.7 hydroxyls per nm² to about 8 hydroxyls per nm², about 1.8 hydroxyls per nm² to about 8 hydroxyls per nm², about 1.9 hydroxyls per nm² to about 8 hydroxyls per nm², about 2.0 hydroxyls per nm² to about 8 hydroxyls per nm², about 2.2 hydroxyls per nm² to about 8 hydroxyls per nm², about 2.4 hydroxyls per nm² to about 8 hydroxyls per nm², about 2.6 hydroxyls per nm² to about 8 hydroxyls per nm², about 2.8 hydroxyls per nm² to about 8 hydroxyls per nm², about 3 hydroxyls per nm² to about 8 hydroxyls per nm², about 3 hydroxyls per nm² to about 7.5 hydroxyls per nm², about 3 hydroxyls per nm² to about 7 hydroxyls per nm², about 3 hydroxyls per nm² to about 6.5 hydroxyls per nm², about 3 hydroxyls per nm² to about 6 hydroxyls per nm², or about 4 hydroxyls per nm² to about 6 hydroxyls per nm². In some embodiments, the colloidal silica particles (e.g., negatively charged colloidal silica particles) have a surface area and the surface area has a surface hydroxyl group density of from about 1.5 hydroxyls per nm² to about 8 hydroxyls per nm².

The surface hydroxyl group density of the silica particles (e.g., negatively charged colloidal silica particles) can be determined using any suitable method. In an embodiment, an aqueous dispersion of the silica particles can be adjusted to have a pH of 4.0 to prepare a titration sample. The titration sample can be titrated with an aqueous sodium hydroxide solution having a known concentration to a pH of 9.0 to determine the number of hydroxyl groups present in the titration sample. The surface area of the silica particles can be determined using any suitable method, for example, by the BET method. The number of hydroxyl groups per nm² can thus be determined.

The silica particles (e.g., negatively charged colloidal silica particles) can be surface-modified using any suitable method. In some embodiments, the silica particles are dispersed in a carrier such as water and are then surface-treated with a suitable source of aluminum ions. For example, an aqueous dispersion of silica particles can be treated with an aqueous solution of an aluminum salt (e.g., an aluminum salt described herein) such that the surface of the silica particles becomes associated with the aluminum ions. Without wishing to be bound by any particular theory, the association of the aluminum ions with the surface of the silica particles is believed to involve bonding with silanol groups found on the surface of the silica particles. In certain embodiments, the aluminum ions are associated with the surface of the silica particle, and are not within the interior of the particles.

The silica particles (e.g., negatively charged colloidal silica particles) can have any suitable amount of aluminum ions associated with the surface of the silica particle. For example, the silica particles can comprise about 0.1 or more, for example, about 0.11 or more, about 0.12 or more, about 0.13 or more, about 0.14 or more, or about 0.15 or more aluminum ions per nm² of the surface area of the particles. Alternatively, or in addition, the silica particles can comprise about 0.2 or less, for example, about 0.19 or less, about 0.18 or less, about 0.17 or less, or about 0.16 or less) of aluminum ions per nm² of the surface area of the particles. Thus, the silica particles can comprise an amount of aluminum ions per nm² of the surface area of the particles bounded by any two of the aforementioned endpoints. For example, the silica particles can comprise about 0.1 to about 0.2, about 0.1 to about 0.19, about 0.1 to about 0.18, about 0.1 to about 0.17, about 0.1 to about 0.16, about 0.11 to about 0.2, about 0.12 to about 0.2, about 0.13 to about 0.2, about 0.14 to about 0.2, or about 0.15 to about 0.2 of aluminum ions per nm² of the surface area of the particles.

The number of aluminum ions per nm² of the surface area of the particles can be determined using any suitable method. In some embodiments, the surface area can be determined, for example, using a BET method. For example, a dispersion of silica particles can be treated with an aqueous solution having a known concentration of aluminum ions. After a suitable treatment period, the concentration of aluminum ions remaining in solution can be determined. The difference in starting aluminum ion concentration and the concentration after treatment represents the amount of aluminum ions associated with the surface of the silica particles, thereby allowing calculation of the number of aluminum ions per nm² of the surface area of the particles. In other embodiments, the aluminum ions per nm² of the surface area of the particles can be determined, for example, using inductively coupled plasma (ICP) mass spectrometry to determine the amount of aluminum in the composition containing the surface-modified silica particles, which in turn can be compared to the surface area of the particles to calculate the aluminum ions per nm² of the surface area of the particles.

In embodiments where the silica abrasive is doped with the aluminum ions, the silica abrasive can be doped with any suitable amount of aluminum ions. For example, the silica particles can comprise about 0.01 wt. % or more, about 0.05 wt. % or more, or about 0.1 wt. % or more aluminum ions (i.e., aluminum) based on total mass of the silica abrasive. Alternatively, or in addition, the silica particles can comprise about 5 wt. % or less, about 2 wt. % or less, about 1 wt. % or less, or about 0.5 wt. % or less aluminum ions (i.e., aluminum) based on total mass of the silica abrasive. Thus, the silica particles can comprise an amount of aluminum ions (i.e., aluminum) based on total mass of the silica abrasive bounded by any two of the aforementioned endpoints. For example, the silica particles can comprise about 0.01 wt. % to about 5 wt. %, about 0.05 wt. % to about 5 wt. %, about 0.1 wt. % to about 5 wt. %, about 0.01 wt. % to about 2 wt. %, about 0.05 wt. % to about 2 wt. %, about 0.1 wt. % to about 2 wt. %, about 0.01 wt. % to about 1 wt. %, about 0.05 wt. % to about 1 wt. %, about 0.1 wt. % to about 1 wt. %, about 0.01 wt. % to about 0.5 wt. %, about 0.05 wt. % to about 0.5 wt. %, or about 0.1 wt. % to about 0.5 wt. % aluminum ions (i.e., aluminum) based on total mass of the silica abrasive.

Alternatively, or additionally, the aluminum ions are present in the polishing composition as an aluminum salt. The aluminum salt can be any suitable salt containing Al(III). In some embodiments, the aluminum salt is aluminum hydroxide, aluminum chloride, aluminum chlorohydrate, aluminum sulfate, alum, aluminum iodide, aluminum nitrate, aluminum phosphate, or a combination thereof. In certain embodiments, the polishing composition comprises aluminum ions, wherein (i) the aluminum ions are present in the polishing composition as an aluminum salt and/or (ii) the silica particles (e.g., negatively charged colloidal silica particles) are surface-modified with the aluminum ions, i.e., the aluminum ions are associated with the surface of the silica particle, and are not within the interior of the particles.

In some embodiments, the chemical-mechanical polishing composition further comprises an iron cation. The iron cation, when present, can exist as ferric iron (i.e., iron III) or ferrous iron (i.e., iron II), and can be added to the composition as any suitable iron-containing salt. For example, the iron cation, when present, can result from the addition of iron nitrates, iron sulfates, iron halides (including fluorides, chlorides, bromides, and iodides, as well as perchlorates, perbromates, and periodates), and organic iron compounds such as iron acetates, acetylacetonates, citrates, gluconates, malonates, oxalates, phthalates, succinates, and combinations thereof to the polishing composition.

The polishing composition can comprise any suitable amount of the iron cation, when present. The polishing composition can comprise about 0.01 ppm or more of the iron cation, for example, 0.1 ppm or more, about 0.5 ppm or more, about 1 ppm or more, about 5 ppm or more, about 10 ppm or more, about 20 ppm or more, about 50 ppm or more, or about 100 ppm or more. Alternatively, or in addition, the polishing composition can comprise about 1000 ppm or less of the iron cation, for example, about 900 ppm or less, about 800 ppm or less, about 700 ppm or less, about 600 ppm or less, about 500 ppm or less, about 400 ppm or less, about 300 ppm or less, about 200 ppm or less, about 100 ppm or less, about 80 ppm or less, about 60 ppm or less, or about 40 ppm or less. Thus, the polishing composition can comprise the iron cation in an amount bounded by any two of the aforementioned endpoints. For example, the polishing composition can comprise about 0.01 ppm to about 1000 ppm of the iron cation, e.g., about 0.01 ppm to about 500 ppm of the iron cation, about 0.01 ppm to about 100 ppm of the iron cation, about 0.01 ppm to about 80 ppm, about 0.01 ppm to about 60 ppm, about 0.01 ppm to about 40 ppm, about 0.1 ppm to about 100 ppm, about 0.1 ppm to about 80 ppm, about 0.1 ppm to about 60 ppm, about 0.1 ppm to about 40 ppm, about 1 ppm to about 1000 ppm, about 1 ppm to about 500 ppm, about 1 ppm to about 100 ppm, about 1 ppm to about 80 ppm, about 1 ppm to about 60 ppm, about 1 ppm to about 40 ppm, about 10 ppm to about 1000 ppm, about 10 ppm to about 500 ppm, about 10 ppm to about 100 ppm, about 10 ppm to about 80 ppm, about 10 ppm to about 60 ppm, about 10 ppm to about 40 ppm, about 50 ppm to about 1000 ppm, about 50 ppm to about 500 ppm, about 50 ppm to about 100 ppm, about 50 ppm to about 80 ppm, about 100 ppm to about 1000 ppm, or about 100 ppm to about 500 ppm.

Without wishing to be bound by any particular theory, it is believed that increasing concentration of iron cation produces higher carbon-based film removal rates. However, it is also believed that higher iron cation concentration may be correlated with multiple defect issues when polishing commercially available carbon-based films. In some embodiments, the iron cation is present in the polishing composition in an amount of about 1 ppm to about 1000 ppm based on the total weight of the polishing composition. In certain embodiments, the iron cation is present in the polishing composition in an amount of about 10 ppm to about 500 ppm based on the total weight of the polishing composition. In some embodiments, the chemical-mechanical polishing composition does not contain an iron cation.

In some embodiments, the chemical-mechanical polishing composition further comprises a ligand (e.g., a ligand for the iron cation). The ligand, when present, can be any suitable ligand, many of which are known in the art. In some embodiments, the ligand comprises an alkene moiety, an alkyne moiety, a diacid moiety, an alcohol moiety, or a combination thereof. For example, the ligand can be any compound (e.g., organic compound) comprising an alkene moiety; an alkyne moiety; a diacid moiety; an alcohol moiety; an alkene moiety and a diacid moiety; an alkene moiety and an alcohol moiety; an alkene moiety, a diacid moiety, and an alcohol moiety; an alkyne moiety and a diacid moiety; an alkyne moiety and an alcohol moiety; an alkyne moiety, a diacid moiety, and an alcohol moiety; or an alkene moiety, an alkyne moiety, a diacid moiety, and an alcohol moiety. In some embodiments, the ligand comprises an alkene moiety and a diacid moiety; or an alkyne moiety and an alcohol moiety.

Exemplary ligands include, but are not limited to 3,5-dimethyl-1-hexyn-3-ol, 2,4,7,9-tetramethyl-5-decyne-4,7-diol, 2,4,7,9-tetramethyl-5-decyne-4,7-diol ethoxylate, 2,5-dimethyl-3-hexyne-2,5-diol, 3-methyl-1-pentyn-3-ol, phosphoric acid, hydroxyethylidene diphosphonic acid, phthalic acid, isophthalic acid, terephthalic acid, citric acid, adipic acid, oxalic acid, malonic acid, fumaric acid, aspartic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, tartaric acid, salts thereof, and combinations thereof. In some embodiments, the ligand is phosphoric acid, hydroxyethylidene diphosphonic acid, phthalic acid, isophthalic acid, terephthalic acid, citric acid, adipic acid, oxalic acid, malonic acid, fumaric acid, aspartic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, tartaric acid, a salt thereof, or a combination thereof. In certain embodiments, the ligand is malonic acid or a salt thereof.

The polishing composition can comprise any suitable amount of the ligand, when present. For example, the polishing composition can comprise about 10 ppm or more of the ligand, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the ligand, for example, about 800 ppm or less, about 600 ppm or less, about 400 ppm or less, about 200 ppm or less, about 100 ppm or less, about 80 ppm or less, about 60 ppm or less, or about 40 ppm or less. Thus, the polishing composition can comprise the ligand in an amount bounded by any two of the aforementioned endpoints. For example, the polishing composition can comprise about 10 ppm to about 1000 ppm of the ligand, e.g., about 10 ppm to about 800 ppm, about 10 ppm to about 600 ppm, about 10 ppm to about 400 ppm, about 10 ppm to about 200 ppm, about 10 ppm to about 100 ppm, about 10 ppm to about 80 ppm, about 10 ppm to about 60 ppm, about 10 ppm to about 40 ppm, about 20 ppm to about 1000 ppm of the surfactant, about 20 ppm to about 800 ppm, about 20 ppm to about 600 ppm, about 20 ppm to about 400 ppm, about 20 ppm to about 200 ppm, about 20 ppm to about 100 ppm, about 20 ppm to about 80 ppm, about 20 ppm to about 60 ppm, or about 20 ppm to about 40 ppm.

The iron cation (when present) and the ligand (when present) can be present in the polishing composition in any suitable molar ratio. However, generally, the ligand is present in a molar excess relative to the iron cation. In some embodiments, the iron cation and the ligand are present in the composition in a molar ratio of from 1:1 to 1:5, for example, from 1:1 to 1:4, from 1:1 to 1:3, from 1:1 to 1:2, from 4:5 to 1:5, from 4:5 to 1:4, from 4:5 to 1:3, from 4:5 to 1:2, from 2:3 to 1:5, from 2:3 to 1:4, from 2:3 to 1:3, or from 2:3 to 1:2. In some embodiments, the iron cation and the ligand are present in the composition in a molar ratio of from 1:1 to 1:5. In some embodiments, the iron cation and the ligand are present in the composition in a molar ratio of from 1:1 to 1:3. In certain embodiments, the iron cation and the ligand are present in the composition in a molar ratio of about 1:2. In some embodiments, the chemical-mechanical polishing composition does not contain a ligand.

In some embodiments, the chemical-mechanical polishing composition further comprises a cationic polymer. The cationic polymer, when present, can comprise any suitable cationic monomer capable of undergoing free radical polymerization and/or addition polymerization. In some embodiments, the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), salts thereof, and combinations thereof. It will be understood from the foregoing list, that any alternative anion counterion (e.g., bromide, iodide, sulfate, methanesulfonate, and phosphate) is also suitable. Alternatively, the cationic polymer can comprise a cationic amino acid monomer. For example, in some embodiments, the cationic polymer comprises arginine, histidine, or lysine. In certain embodiments, the cationic polymer is polylysine. It will be understood that polylysine may include &-polylysine and/or α-polylysine composed of D-lysine and/or L-lysine. The polylysine may thus include α-poly-L-lysine, α-poly-D-lysine,-poly-L-lysine, ε-poly-D-lysine, salts thereof, and mixtures thereof.

Exemplary cationic polymers include, but are not limited to, poly(vinylimidazolium), poly(methacryloyloxyethyltrimethylammonium) chloride (polyMADQUAT), poly(diallyldimethylammonium) chloride (polyDADMAC) (e.g., Polyquaternium-6), poly(dimethylamine-co-epichlorohydrin), poly[bis(2-chloroethyl) ether-alt-1,3-bis[3-(dimethylamino)propyl]urea] (e.g., Polyquaternium-2), copolymers of hydroxyethyl cellulose and diallyldimethylammonium (e.g., Polyquaternium-4), copolymers of acrylamide and diallyldimethylammonium (e.g., Polyquaternium-7), quaternized hydroxyethylcellulose ethoxylate (e.g., Polyquaternium-10), copolymers of vinylpyrrolidone and quaternized dimethylaminoethyl methacrylate (e.g., Polyquaternium-11), copolymers of vinylpyrrolidone and quaternized vinylimidazole (e.g., Polyquaternium-16), a terpolymer of vinylcaprolactam, vinylpyrrolidone, and quaternized vinylimidazole (e.g., Polyquaternium-46), 3-methyl-1-vinylimidazolium methyl sulfate-N-vinylpyrrolidone copolymer (e.g., Polyquaternium-44), copolymers of vinylpyrrolidone and diallyldimethylammonium, Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, salts thereof, and combinations thereof. In some embodiments, the cationic polymer is or comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly[bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof. In certain embodiments, the cationic polymer is or comprises poly(diallyldimethylammonium) chloride (polyDADMAC) or a salt thereof.

The polishing composition can comprise any suitable amount of the cationic polymer, when present. The polishing composition can comprise about 10 ppm or more of the cationic polymer, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the cationic polymer, for example, about 800 ppm or less, about 600 ppm or less, about 400 ppm or less, about 200 ppm or less, or about 100 ppm or less. Thus, the polishing composition can comprise the cationic polymer in an amount bounded by any two of the aforementioned endpoints. For example, the polishing composition can comprise about 10 ppm to about 1000 ppm of the cationic polymer, e.g., about 10 ppm to about 800 ppm, about 10 ppm to about 600 ppm, about 10 ppm to about 400 ppm, about 10 ppm to about 200 ppm, about 10 ppm to about 100 ppm, about 25 ppm to about 1000 ppm, about 25 ppm to about 800 ppm, about 25 ppm to about 600 ppm, about 25 ppm to about 400 ppm, about 25 ppm to about 200 ppm, or about 25 ppm to about 100 ppm. In some embodiments, the chemical-mechanical polishing composition does not contain a cationic polymer.

The cationic polymer, when present, can exist as any suitable structure type. For example, the cationic polymer can exist as an alternating polymer, a random polymer, a block polymer, a graft polymer, a linear polymer, a branched polymer, or a combination thereof. The cationic polymer can contain a single monomer unit, or any suitable number of different monomer units. For example, the cationic polymer can contain 2 different monomer units, 3 different monomer units, 4 different monomer units, 5 different monomer units, or 6 different monomer units. The cationic monomers of the cationic polymer can exist in any suitable concentration and any suitable proportion.

The cationic polymer, when present, can have any suitable weight average molecular weight. The cationic polymer can have a weight average molecular weight of about 150 g/mol or more, for example, about 300 g/mol or more, about 500 g/mol or more, about 600 g/mol or more, about 750 g/mol or more, about 1000 g/mol or more, about 1500 g/mol or more, about 2000 g/mol or more, about 2500 g/mol or more, about 3000 g/mol or more, about 3500 g/mol or more, about 4000 g/mol or more, about 4500 g/mol or more, about 5000 g/mol or more, about 5500 g/mol or more, about 6000 g/mol or more, about 6500 g/mol or more, about 7000 g/mol or more, or about 7500 g/mol or more. Alternatively, or in addition, the cationic polymer can have a weight average molecular weight of about 10000 g/mol or less, for example, about 9000 g/mol or less, about 8000 g/mol or less, about 7500 g/mol or less, about 7000 g/mol or less, about 6500 g/mol or less, about 6000 g/mol or less, about 5500 g/mol or less, about 5000 g/mol or less, about 4500 g/mol or less, about 4000 g/mol or less, about 3500 g/mol or less, about 3000 g/mol or less, about 2500 g/mol or less, or about 2000 g/mol or less. Thus, cationic polymer can have a weight average molecular weight bounded by any two of the aforementioned endpoints. For example, the cationic polymer can have a weight average molecular weight of about 150 g/mol to about 10000 g/mol, e.g., about 300 g/mol to about 9000 g/mol, about 500 g/mol to about 8000 g/mol, about 150 g/mol to about 7000 g/mol, about 150 g/mol to about 6000 g/mol, about 150 g/mol to about 5000 g/mol, about 150 g/mol to about 2000 g/mol, about 1000 g/mol to about 10000 g/mol, about 1000 g/mol to about 9000 g/mol, about 1000 g/mol to about 8000 g/mol, about 1000 g/mol to about 7000 g/mol, about 1000 g/mol to about 6000 g/mol, or about 1000 g/mol to about 5000 g/mol.

In some embodiments, the polishing composition further comprises a nonionic polymer. The nonionic polymer, when present, can be any suitable polymer without a cationic or anionic charge at a pH of about 1 to about 7. In some embodiments, the nonionic polymer, when present, is selected from a polyalkylene glycol, polyetheramine, polyethylene oxide/polypropylene oxide copolymer, polyacrylamide, polyvinylpyrrolidone, siloxane polyalkyleneoxide copolymer, hydrophobically modified polyacrylate copolymer, hydrophilic nonionic polymer, polysaccharides, and combinations thereof. In certain embodiments, the nonionic polymer, when present, is polyvinylpyrrolidone, polyalkylene glycol (e.g., polyethylene glycol (PEG) or polypropylene oxide (PPO)), a polyethylene oxide/polypropylene oxide copolymer, or a combination thereof. In preferred embodiments, the nonionic polymer, when present, is polyvinylpyrrolidone.

The nonionic polymer, when present, can exist as any suitable structure type. For example, the nonionic polymer can exist as an alternating polymer, a random polymer, a block polymer, a graft polymer, a linear polymer, a branched polymer, or a combination thereof. The nonionic polymer can contain a single monomer unit, or any suitable number of different monomer units. For example, the nonionic polymer can contain 2 different monomer units, 3 different monomer units, 4 different monomer units, 5 different monomer units, or 6 different monomer units. The nonionic monomers of the nonionic polymer can exist in any suitable concentration and any suitable proportion.

The non-ionic polymer, when present, can have any suitable weight average molecular weight. The non-ionic polymer can have a weight average molecular weight of about 400 g/mol or more, for example, about 500 g/mol or more, about 600 g/mol or more, about 750 g/mol or more, about 1000 g/mol or more, about 1500 g/mol or more, about 2000 g/mol or more, about 2500 g/mol or more, about 3000 g/mol or more, about 3500 g/mol or more, about 4000 g/mol or more, about 4500 g/mol or more, about 5000 g/mol or more, about 5500 g/mol or more, about 6000 g/mol or more, about 6500 g/mol or more, about 7000 g/mol or more, or about 7500 g/mol or more. Alternatively, or in addition, the non-ionic polymer can have a weight average molecular weight of about 10000 g/mol or less, for example, about 9000 g/mol or less, about 8000 g/mol or less, about 7500 g/mol or less, about 7000 g/mol or less, about 6500 g/mol or less, about 6000 g/mol or less, about 5500 g/mol or less, about 5000 g/mol or less, about 4500 g/mol or less, about 4000 g/mol or less, about 3500 g/mol or less, about 3000 g/mol or less, about 2500 g/mol or less, or about 2000 g/mol or less. Thus, the non-ionic polymer can have a weight average molecular weight bounded by any two of the aforementioned endpoints. For example, the non-ionic polymer can have a weight average molecular weight of about 400 g/mol to about 10000 g/mol, e.g., about 400 g/mol to about 9000 g/mol, about 400 g/mol to about 8000 g/mol, about 400 g/mol to about 7000 g/mol, about 400 g/mol to about 6000 g/mol, about 400 g/mol to about 5000 g/mol, about 1000 g/mol to about 10000 g/mol, about 1000 g/mol to about 9000 g/mol, about 1000 g/mol to about 8000 g/mol, about 1000 g/mol to about 7000 g/mol, about 1000 g/mol to about 6000 g/mol, or about 1000 g/mol to about 5000 g/mol.

The polishing composition can comprise any suitable amount of the nonionic polymer, when present. The polishing composition can comprise about 25 ppm or more of the nonionic polymer, for example, about 50 ppm or more, about 100 ppm or more, or about 200 ppm or more. Alternatively, or in addition, the polishing composition can comprise about 5000 ppm or less of the nonionic polymer, for example, about 4000 ppm or less, about 3000 ppm or less, about 2000 ppm or less, or about 1000 ppm or less. Thus, the polishing composition can comprise the nonionic polymer in an amount bounded by any two of the aforementioned endpoints. For example, the polishing composition can comprise about 25 ppm to about 5000 ppm of the nonionic polymer, e.g., about 25 ppm to about 400 ppm, about 25 ppm to about 3000 ppm, about 25 ppm to about 2000 ppm, about 25 ppm to about 1000 ppm, about 50 ppm to about 5000 ppm, about 50 ppm to about 4000 ppm, about 50 ppm to about 3000 ppm, about 50 ppm to about 2000 ppm, about 50 ppm to about 1000 ppm, about 100 ppm to about 5000 ppm, or about 100 ppm to about 1000 ppm. In some embodiments, the chemical-mechanical polishing composition does not contain a nonionic polymer.

The chemical-mechanical polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition. Typically, the chemical-mechanical polishing composition has a pH of about 1 to about 4 at the point-of-use (e.g., a pH of about 1 to about 3, of about 1 to about 2, of about 2 to about 4, of about 2 to about 3, or of about 3 to about 4). In some embodiments, the polishing composition has a pH of about 1 to about 3 at the point-of-use. In certain embodiments, the polishing composition has a pH of about 2 to about 3 at the point-of-use.

The pH of the chemical-mechanical polishing composition can be adjusted using any suitable compound capable of adjusting the pH of the polishing composition. The pH adjusting compound desirably is water-soluble and compatible with the other components of the polishing composition. Non-limiting examples of suitable acids for adjusting the pH of the polishing composition include nitric acid, hydrochloric acid, sulfuric acid, phosphoric acid, and organic acids such as formic acid and acetic acid. Non-limiting examples of suitable bases for adjusting the pH of the polishing composition include sodium hydroxide, potassium hydroxide, and ammonium hydroxide.

In some embodiments, the chemical-mechanical polishing composition further comprises one or more additives such as, for example, conditioners, acids (e.g., sulfonic acids), complexing agents (e.g., anionic polymeric complexing agents), chelating agents, biocides, scale inhibitors, dispersants, and/or conductivity adjustors. In certain embodiments, the polishing composition further comprises a biocide. A biocide, when present, can be any suitable biocide and can be present in the polishing composition in any suitable amount. A suitable biocide is an isothiazolinone biocide. Typically, the polishing composition comprises about 1 ppm to about 200 ppm biocide (e.g., about 1 ppm to about 100 ppm or about 1 ppm to about 50 ppm), preferably about 10 ppm to about 20 ppm biocide.

In some embodiments, the chemical-mechanical polishing composition further comprises an oxidizing agent. The oxidizing agent can be any suitable oxidizing agent. Without wishing to be bound by any particular theory, it is believed that the oxidizing agent increases the removal rate of a carbon-based film when used to polish a substrate comprising the same. Non-limiting examples of a suitable oxidizing agent include oxone, cerium ammonium nitrate, a peroxide (e.g., hydrogen peroxide), a periodate (e.g., sodium periodate or potassium periodate), an iodate (e.g., sodium iodate, potassium iodate, or ammonium iodate), a persulfate (e.g., sodium persulfate, potassium persulfate, or ammonium persulfate), a chlorate (e.g., sodium chlorate or potassium chlorate), a chromate (e.g., sodium chromate or potassium chromate), a permanganate (e.g., sodium permanganate, potassium permanganate, or ammonium permanganate), a bromate (e.g., sodium bromate or potassium bromate), a perbromate (e.g., sodium perbromate or potassium perbromate), a ferrate (e.g., potassium ferrate), a perrhenate (e.g., ammonium perrhenate), a perruthenate (e.g., tetrapropylammonium perruthenate), and a combination thereof. In some embodiments, the oxidizing agent is hydrogen peroxide. The polishing composition can comprise any suitable amount of the oxidizing agent. For example, the polishing composition can comprise about 0.1 wt. % to about 5 wt. % of the oxidizing agent (e.g., about 0.5 wt. % to about 3 wt. % or about 1 wt. % to about 3 wt. % of the oxidizing agent).

In some embodiments, the chemical-mechanical polishing composition is free of oxidizing agents. As used herein, the phrase “free of oxidizing agents” means (a) that the composition does not contain an oxidizing agent or (b) that the composition includes no more than trace contaminant amounts of oxidizing materials.

The chemical-mechanical polishing composition comprises water. The water can be any suitable water including, for example, deionized water or distilled water. In some embodiments, the chemical-mechanical polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like. In certain embodiments, the chemical-mechanical polishing composition comprises pure water.

In some embodiments, the chemical-mechanical polishing composition comprises, consists essentially of, or consists of: (a) a silica abrasive, (b) aluminum ions, (c) optional biocide, (d) optional pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3).

In some embodiments, the chemical-mechanical polishing composition comprises, consists essentially of, or consists of: (a) a silica abrasive, (b) aluminum ions, (c) biocide, (d) optional pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3).

In some embodiments, the chemical-mechanical polishing composition comprises, consists essentially of, or consists of: (a) a silica abrasive, (b) aluminum ions, (c) biocide, (d) pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3).

The chemical-mechanical polishing composition can be produced by any suitable technique, many of which are known to those skilled in the art. The polishing composition can be prepared in a batch or continuous process. Generally, the polishing composition is prepared by combining the components of the polishing composition in any order. The term “component” as used herein includes individual ingredients (e.g., silica abrasive, aluminum ions, optional biocide, optional pH adjusting compound, and/or any other optional additive, etc.) as well as any combination of ingredients (e.g., silica abrasive, aluminum ions, optional biocide, optional pH adjusting compound, and/or any other optional additive, etc.).

For example, the polishing composition can be prepared by (i) providing all or a portion of the liquid carrier, (ii) dispersing the silica abrasive, aluminum ions, optional biocide, and/or any other optional additive, etc., using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., aluminum ions, optional biocide, and/or any other optional additive, etc.) in a silica abrasive slurry, (ii) providing one or more components (e.g., aluminum ions, optional biocide, and/or any other optional additive, etc.) in an additive solution, (iii) combining the silica abrasive slurry and the additive solution to form a mixture, (iv) optionally adding suitable amounts of any other optional additives to the mixture, and (v) adjusting the pH of the mixture as appropriate.

The polishing composition can be supplied as a one-package system comprising a silica abrasive, aluminum ions, optional biocide, optional pH adjusting compound, and/or any other optional additive, and water. Alternatively, the polishing composition of the invention can be supplied as a two-package system comprising a silica abrasive slurry in a first package and an additive solution in a second package, wherein the silica abrasive slurry consists essentially of, or consists of, a silica abrasive, and water, and wherein the additive solution consists essentially of, or consists of, aluminum ions, optional biocide, optional pH adjusting compound, and/or any other optional additive. The two-package system allows for the adjustment of polishing composition characteristics by changing the blending ratio of the two packages, i.e., the silica abrasive slurry and the additive solution.

Various methods can be employed to utilize such a two-package polishing system. For example, the silica abrasive slurry and additive solution can be delivered to the polishing table by different pipes that are joined and connected at the outlet of supply piping. The silica abrasive slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use”if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high-pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the silica abrasive, aluminum ions, optional biocide, optional pH adjusting compound, and any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that the aluminum ions, optional biocide, optional pH adjusting compound, and/or any other optional additive are at least partially or fully dissolved in the concentrate.

The invention further provides a method of chemically-mechanically polishing a substrate comprising: (i) providing a substrate, (ii) providing a polishing pad, (iii) providing a chemical-mechanical polishing composition comprising: (a) a silica abrasive, (b) aluminum ions, and (c) water, wherein (i) the aluminum ions are present in the polishing composition as an aluminum salt and/or (ii) the silica abrasive is doped with the aluminum ions, and wherein the polishing composition has a pH of about 1 to about 4, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the invention provides a method of chemically-mechanically polishing a substrate comprising: (i) providing a substrate, (ii) providing a polishing pad, (iii) providing a chemical-mechanical polishing composition comprising, consisting essentially of, or consisting of: (a) a silica abrasive, (b) aluminum ions, (c) optional biocide, (d) optional pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the invention provides a method of chemically-mechanically polishing a substrate comprising: (i) providing a substrate, (ii) providing a polishing pad, (iii) providing a chemical-mechanical polishing composition comprising, consisting essentially of, or consisting of: (a) a silica abrasive, (b) aluminum ions, (c) biocide, (d) optional pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the invention provides a method of chemically-mechanically polishing a substrate comprising: (i) providing a substrate, (ii) providing a polishing pad, (iii) providing a chemical-mechanical polishing composition comprising, consisting essentially of, or consisting of: (a) a silica abrasive, (b) aluminum ions, (c) biocide, (d) pH adjusting compound, and (e) water, wherein (i) the aluminum ions are present in the polishing composition as an aluminum salt and/or (ii) the silica abrasive is doped with the aluminum ions, and wherein the polishing composition has a pH of about 1 to about 4 (e.g., a pH of about 1 to about 3 or a pH of about 2 to about 3), (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of a low dielectric material. Suitable substrates include wafers used in the semiconductor industry. The wafers typically comprise or consist of, for example, a metal, metal oxide, metal nitride, metal composite, metal alloy, a low dielectric material, or combinations thereof. The method of the invention is particularly useful for polishing substrates comprising carbon-based films (e.g., carbon hard-mask materials). In some embodiments, the substrate comprises a carbon-based film, wherein at least a portion of the carbon-based film is abraded at a removal rate (Å/min) to polish the substrate.

In certain embodiments, the substrate comprises a carbon-based film. The carbon based-film can be any suitable material (e.g., low dielectric material) containing carbon, many of which are known in the art. In some embodiments, the carbon-based film comprises more than about 50 wt. % carbon, for example, more than about 60 wt. % carbon, more than about 70 wt. % carbon, more than about 80 wt. % carbon, more than about 90 wt. % carbon, or more than about 95 wt. % carbon. The carbon based-film can have any suitable phase. For example, the carbon-based film can be amorphous, crystalline, or a combination thereof. In certain embodiments, the carbon-based film is amorphous. Exemplary carbon-based films are described in Weigand, et al. (“Evaluating spin-on carbon materials at low temperatures for high wiggling resistance,” Advanced Etch Technology for Nanopatterning II, Vol. 8685, International Society for Optics and Photonics, 2013) and Kim et al. (“Study on the etching characteristics of amorphous carbon layer in oxygen plasma with carbonyl sulfide,” J. Vac. Sci. Technol. A, 31, 021301, pp. 1-7 (2013)).

In some embodiments, the substrate comprises a carbon-based film and at least a portion of the carbon-based film is abraded at a removal rate (Å/min) to polish the substrate. The chemical-mechanical polishing composition of the invention desirably exhibits a high removal rate when polishing a substrate comprising a carbon-based film according to a method of the invention. For example, when polishing substrates comprising a carbon-based film in accordance with an embodiment of the invention, the polishing composition desirably exhibits a removal rate of the carbon-based film of about 500 Å/min or higher, about 600 Å/min or higher, about 700 Å/min or higher, about 800 Å/min or higher, about 900 Å/min or higher, about 1,000 Å/min or higher, about 1,100 Å/min or higher, about 1,200 Å/min or higher, about 1,500 Å/min or higher, about 2,000 Å/min or higher, about 3,000 Å/min or higher, or about 4,000 Å/min or higher.

In some embodiments, the substrate further comprises silicon oxide, silicon nitride, polysilicon, or titanium nitride, and at least a portion of the silicon oxide, silicon nitride, polysilicon, or titanium nitride is abraded at a removal rate (Å/min) to polish the substrate. In embodiments where the substrate further comprises silicon oxide, silicon nitride, polysilicon, or titanium nitride, the removal rate (Å/min) of the carbon-based film is greater than the removal rate (Å/min) of the silicon oxide, silicon nitride, polysilicon, and/or titanium nitride. In other words, in some embodiments, the polishing composition and method exhibit selective removal of the carbon-based film with little to no removal of silicon oxide, silicon nitride, polysilicon, or titanium nitride. For example, the removal rate (Å/min) of the carbon-based film can be at least 10 times greater than the removal rate (Å/min) of the silicon oxide, silicon nitride, polysilicon, and/or titanium nitride, at least 20 times greater than the removal rate (Å/min) of the silicon oxide, silicon nitride, polysilicon, and/or titanium nitride, at least 40 times greater than the removal rate (Å/min) of the silicon oxide, silicon nitride, polysilicon, and/or titanium nitride, at least 50 times greater than the removal rate (Å/min) of the silicon oxide, silicon nitride, polysilicon, and/or titanium nitride, at least 100 times greater than the removal rate (Å/min) of the silicon oxide, silicon nitride, polysilicon, or titanium nitride, or at least 200 times greater than the removal rate (Å/min) of the silicon oxide, silicon nitride, polysilicon, and/or titanium nitride.

In embodiments, where the substrate further comprises silicon oxide, the silicon oxide can be any suitable silicon oxide, many of which are known in the art. Suitable types of silicon oxide include, but are not limited to, silicon oxide films derived from tetraethyl orthosilicate (TEOS), borophosphosilicate glass (BPSG), plasma enhanced tetraethylorthosilicate (PETEOS), thermal oxide, undoped silicate glass, and high-density plasma (HDP) oxide. The chemical-mechanical polishing composition of the invention desirably exhibits a low removal rate when polishing a substrate comprising silicon oxide according to a method of the invention. For example, when polishing substrates comprising silicon oxide in accordance with an embodiment of the invention, the polishing composition desirably exhibits a removal rate of silicon oxide of about 500 Å/min or lower, for example, about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a silicon oxide removal rate that is too low to be detected. In some embodiments, the removal rate (Å/min) of the carbon-based film is at least 50 (e.g., 50-1000, 50-500, 50-400, 50-300, or 50-200) times greater than the removal rate (Å/min) of the silicon oxide. In some embodiments, the removal rate (Å/min) of the carbon-based film is at least 100 (e.g., 100-1000, 100-500, 100-400, 100-300, or 100-200) times greater than the removal rate (Å/min) of the silicon oxide. In certain embodiments, the removal rate (Å/min) of the carbon-based film is at least 200 (e.g., 200-1000, 200-500, 200-400, or 200-300) times greater than the removal rate (Å/min) of the silicon oxide.

In embodiments, where the substrate further comprises polysilicon, the polysilicon can be any suitable polysilicon, many of which are known in the art. The polysilicon can have any suitable phase, and can be amorphous, crystalline, or a combination thereof. The chemical-mechanical polishing composition of the invention desirably exhibits a low removal rate when polishing a substrate comprising polysilicon according to a method of the invention. For example, when polishing substrates comprising polysilicon in accordance with an embodiment of the invention, the polishing composition desirably exhibits a removal rate of polysilicon of about 500 Å/min or lower, for example, about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a polysilicon removal rate that is too low to be detected.

In embodiments, where the substrate further comprises silicon nitride, the silicon nitride can be any suitable silicon nitride, many of which are known in the art. The chemical-mechanical polishing composition of the invention desirably exhibits a low removal rate when polishing a substrate comprising silicon nitride according to a method of the invention. For example, when polishing substrates comprising silicon nitride in accordance with an embodiment of the invention, the polishing composition desirably exhibits a removal rate of silicon nitride of about 500 Å/min or lower, for example, about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a silicon nitride removal rate that is too low to be detected.

In embodiments, where the substrate further comprises titanium nitride, the titanium nitride can be any suitable titanium nitride, many of which are known in the art. The chemical-mechanical polishing composition of the invention desirably exhibits a low removal rate when polishing a substrate comprising titanium nitride according to a method of the invention. For example, when polishing substrates comprising titanium nitride in accordance with an embodiment of the invention, the polishing composition desirably exhibits a removal rate of titanium nitride of about 500 Å/min or lower, for example, about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a titanium nitride removal rate that is too low to be detected.

The polishing composition of the invention desirably exhibits low particle defects when polishing a substrate, as determined by suitable techniques. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 Eminess Technologies), POLITEX™ commercially available from Dow Chemical Company (Newark, DE), and POLYPAS™ 27 commercially available from Fujibo (Osaka, JP), and EPIC™ D100 pads or NEXPLANAR™ E6088 commercially available from Entegris (Aurora, IL).

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511. U.S. Pat. Nos. 5,643,046, 5,658,183, 5,730,642, 5,838,447, 5,872,633. U.S. Pat. Nos. 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

Aspects, including embodiments, of the invention described herein may be beneficial alone or in combination, with one or more other aspects or embodiments. Without limiting the foregoing description, certain non-limiting embodiments of the disclosure numbered 1-56 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a chemical-mechanical polishing composition comprising:
(a) a silica abrasive,
(b) aluminum ions, and
(c) water,
   wherein (i) the aluminum ions are present in the polishing composition as an aluminum salt and/or (ii) the silica abrasive is doped with the aluminum ions, and wherein the polishing composition has a pH of about 1 to about 4.

(2) In embodiment (2) is presented the polishing composition of embodiment (1), wherein the polishing composition comprises about 0.001 wt. % to about 10 wt. % of the silica abrasive.

(3) In embodiment (3) is presented the polishing composition of embodiment (1) or embodiment (2), wherein the polishing composition comprises about 0.05 wt. % to about 5 wt. % of the silica abrasive.

(4) In embodiment (4) is presented the polishing composition of any one of embodiments (1)-(3), wherein the polishing composition has a pH of about 1 to about 3.

(5) In embodiment (5) is presented the polishing composition of any one of embodiments (1)-(4), wherein the polishing composition has a pH of about 2 to about 3.

(6) In embodiment (6) is presented the polishing composition of any one of embodiments (1)-(5), wherein the silica abrasive is colloidal silica.

(7) In embodiment (7) is presented the polishing composition of embodiment (6), wherein the colloidal silica has a surface area and the surface area has a surface hydroxyl group density of from about 1.5 hydroxyls per nm² to about 8 hydroxyls per nm².

(8) In embodiment (8) is presented the polishing composition of any one of embodiments (1)-(7), wherein the silica abrasive has an average particle size of about 40 nm to about 80 nm.

(9) In embodiment (9) is presented the polishing composition of any one of embodiments (1)-(8), wherein the silica abrasive has a negative zeta potential.

(10) In embodiment (10) is presented the polishing composition of any one of embodiments (1)-(9), wherein the aluminum ions are present in the polishing composition as an aluminum salt.

(11) In embodiment (11) is presented the polishing composition of embodiment (10), wherein the aluminum salt is aluminum hydroxide, aluminum chloride, aluminum chlorohydrate, aluminum sulfate, alum, aluminum iodide, aluminum nitrate, aluminum phosphate, or a combination thereof.

(12) In embodiment (12) is presented the polishing composition of any one of embodiments (1)-(9), wherein the silica abrasive is doped with the aluminum ions.

(13) In embodiment (13) is presented the polishing composition of embodiment (12), wherein the silica abrasive is surface-modified with the aluminum ions.

(14) In embodiment (14) is presented the polishing composition of any one of embodiments (1)-(13), wherein the composition further comprises an iron cation.

(15) In embodiment (15) is presented the polishing composition of embodiment (14), wherein the iron cation is present in the polishing composition in an amount of about 1 ppm to about 1000 ppm based on the total weight of the polishing composition.

(16) In embodiment (16) is presented the polishing composition of any one of embodiments (1)-(15), wherein the composition further comprises a ligand.

(17) In embodiment (17) is presented the polishing composition of any one of embodiment (16), wherein the ligand is phosphoric acid, hydroxyethylidene diphosphonic acid, phthalic acid, isophthalic acid, terephthalic acid, citric acid, adipic acid, oxalic acid, malonic acid, fumaric acid, aspartic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, tartaric acid, a salt thereof, or a combination thereof.

(18) In embodiment (18) is presented the polishing composition of embodiment (16) or embodiment (17), wherein the ligand is malonic acid or a salt thereof.

(19) In embodiment (19) is presented the polishing composition of any one of embodiments (16)-(18), wherein the iron cation and the ligand are present in the composition in a molar ratio of from 1:1 to 1:5.

(20) In embodiment (20) is presented the polishing composition of any one of embodiments (16)-(19), wherein the iron cation and the ligand are present in the composition in a molar ratio of from 1:1 to 1:3.

(21) In embodiment (21) is presented the polishing composition of any one of embodiments (1)-(20), wherein the composition further comprises a cationic polymer.

(22) In embodiment (22) is presented the polishing composition of embodiment (21), wherein the cationic polymer comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly[bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

(23) In embodiment (23) is presented the polishing composition of any one of embodiments (1)-(22), wherein the polishing composition further comprises a nonionic polymer and the nonionic polymer is polyvinylpyrrolidone.

(24) In embodiment (24) is presented the polishing composition of any one of embodiments (1)-(23), wherein the polishing composition further comprises a biocide.

(25) In embodiment (25) is presented the polishing composition of any one of embodiments (1)-(24), wherein the polishing composition further comprises an oxidizing agent.

(26) In embodiment (26) is presented a method of chemically-mechanically polishing a substrate comprising:
(i) providing a substrate,
(ii) providing a polishing pad,
(iii) providing a chemical-mechanical polishing composition comprising:
(a) a silica abrasive,
(b) aluminum ions, and
(c) water,
wherein (i) the aluminum ions are present in the polishing composition as an aluminum salt and/or (ii) the silica abrasive is doped with the aluminum ions, and wherein the polishing composition has a pH of about 1 to about 4,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

(27) In embodiment (27) is presented the method of embodiment (26), wherein the polishing composition comprises about 0.001 wt. % to about 10 wt. % of the silica abrasive.

(28) (In embodiment (28) is presented the method of embodiment (26) or embodiment (27), wherein the polishing composition comprises about 0.05 wt. % to about 5 wt. % of the silica abrasive.

(29) In embodiment (29) is presented the method of any one of embodiments (26)-(28), wherein the polishing composition has a pH of about 1 to about 3.

(30) In embodiment (30) is presented the method of any one of embodiments (26)-(29), wherein the polishing composition has a pH of about 2 to about 3.

(31) In embodiment (31) is presented the method of any one of embodiments (26)-(30), wherein the silica abrasive is colloidal silica.

(32) In embodiment (32) is presented the method of embodiment (31), wherein the colloidal silica has a surface area and the surface area has a surface hydroxyl group density of from about 1.5 hydroxyls per nm² to about 8 hydroxyls per nm².

(33) In embodiment (33) is presented the method of any one of embodiments (26)-(32), wherein the silica abrasive has an average particle size of about 40 nm to about 80 nm.

(34) In embodiment (34) is presented the method of any one of embodiments (26)-(33), wherein the silica abrasive has a negative zeta potential.

(35) In embodiment (35) is presented the method of any one of embodiments (26)-(34), wherein the aluminum ions are present in the polishing composition as an aluminum salt.

(36) In embodiment (36) is presented the method of embodiment (35), wherein the aluminum salt is aluminum hydroxide, aluminum chloride, aluminum chlorohydrate, aluminum sulfate, alum, aluminum iodide, aluminum nitrate, aluminum phosphate, or a combination thereof.

(37) In embodiment (37) is presented the method of any one of embodiments (26)-(36), wherein the silica abrasive is doped with the aluminum ions.

(38) In embodiment (38) is presented the method of embodiments (37), wherein the silica abrasive is surface-modified with the aluminum ions.

(39) In embodiment (39) is presented the method of any one of embodiments (26)-(38), wherein the composition further comprises an iron cation.

(40) In embodiment (40) is presented the method of embodiment (39), wherein the iron cation is present in the polishing composition in an amount of about 1 ppm to about 1000 ppm based on the total weight of the polishing composition.

(41) In embodiment (41) is presented the method of any one of embodiments (26)-(40), wherein the composition further comprises a ligand.

(42) In embodiment (42) is presented the method of embodiment (41), wherein the ligand is phosphoric acid, hydroxyethylidene diphosphonic acid, phthalic acid, isophthalic acid, terephthalic acid, citric acid, adipic acid, oxalic acid, malonic acid, fumaric acid, aspartic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, tartaric acid, a salt thereof, or a combination thereof.

(43) In embodiment (43) is presented the method of embodiment (41) or embodiment (42), wherein the ligand is malonic acid or a salt thereof.

(44) In embodiment (44) is presented the method of any one of embodiments (41)-(43), wherein the iron cation and the ligand are present in the composition in a molar ratio of from 1:1 to 1:5.

(45) In embodiment (45) is presented the method of any one of embodiments (41)-(44), wherein the iron cation and the ligand are present in the composition in a molar ratio of from 1:1 to 1:3.

(46) In embodiment (46) is presented the method of any one of embodiments (26)-(45), wherein the composition further comprises a cationic polymer.

(47) In embodiment (47) is presented the method of embodiment (46), wherein the cationic polymer comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly[bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

(48) In embodiment (48) is presented the method of any one of embodiments (26)-(47), wherein the polishing composition further comprises a nonionic polymer and the nonionic polymer is polyvinylpyrrolidone.

(49) In embodiment (49) is presented the method of any one of embodiments (26)-(48), wherein the polishing composition further comprises a biocide.

(50) In embodiment (50) is presented the method of any one of embodiments (26)-(49), wherein the polishing composition further comprises an oxidizing agent.

(51) In embodiment (51) is presented the method of any one of embodiments (26)-(50), wherein the substrate comprises a carbon-based film, and wherein at least a portion of the carbon-based film is abraded at a removal rate (Å/min) to polish the substrate.

(52) In embodiment (52) is presented the method of embodiment (51), wherein the substrate further comprises silicon oxide, silicon nitride, polysilicon, or titanium nitride, and wherein at least a portion of the silicon oxide, silicon nitride, polysilicon, or titanium nitride is abraded at a removal rate (Å/min) to polish the substrate.

(53) In embodiment (53) is presented the method of embodiment (52), wherein the removal rate (Å/min) of the carbon-based film is greater than the removal rate (Å/min) of the silicon oxide, silicon nitride, polysilicon, or titanium nitride.

(54) In embodiment (54) is presented the method of embodiment (52), wherein the substrate further comprises silicon oxide, wherein at least a portion of the silicon oxide is abraded at a removal rate (Å/min) to polish the substrate, and wherein the removal rate (Å/min) of the carbon-based film is at least 50 times greater than the removal rate (Å/min) of the silicon oxide.

(55) In embodiment (55) is presented the method of embodiment (54), wherein the removal rate (Å/min) of the carbon-based film is at least 100 times greater than the removal rate (Å/min) of the silicon oxide.

(56) In embodiment (56) is presented the method of embodiment (55), wherein the removal rate (Å/min) of the carbon-based film is at least 200 times greater than the removal rate (Å/min) of the silicon oxide.

### Examples

These following examples further illustrate the invention but, of course, should not be construed as in any way limiting its scope.

The following abbreviations are used throughout the Examples: removal rate (RR); spin-on carbon (SOC); and tetraethyl orthosilicate (TEOS).

### Example 1

This example demonstrates the preparation of polishing compositions comprising a silica abrasive, aluminum ions, optionally an iron cation, optionally a ligand, and optionally a biocide according to the invention. Polishing Compositions 1A-1H were used, below, to demonstrate the beneficial polishing performance provided by a polishing composition prepared according to the invention.

For each of the compositions used in this example, silica Particle A (i.e., an aluminum-doped silica particle having a doping level of 0.1 wt. % and a negative zeta potential of −42 mV at pH 3), silica Particle B (i.e., an undoped silica particle having a zeta potential of −68 mV at pH 3), and silica Particle C (i.e., an undoped silica particle having a zeta potential of 64 mV at pH 3) were combined with an iron cation (when present), a ligand (when present), and a biocide (when present). The iron cation (i.e., as an iron compound described herein), the ligand (i.e., malonic acid), and the biocide (i.e., PROXEL™ AQ), were added to each of the polishing compositions in the amounts specified in Table 1, and the pH of each polishing composition was adjusted as specified in Table 1. The final compositions (i.e., the compositions as defined in Table 1) were diluted six-fold (i.e., 6×) at the point-of-use (i.e., immediately prior to polishing).

TABLE 1
Polishing Compositions 1A-1H

| Polishing | Silica Abrasive | [Fe] | [ligand] | Biocide | |
|---|---|---|---|---|---|
| Composition | (wt. %) | (wt. %) | (wt. %) | (ppm) | pH |
| Polishing | B (3 wt. %) | 0 | 0 | 300 | 2.15 |
| Composition 1A | | | | | |
| Polishing | C (3 wt. %) | 0 | 0 | 300 | 2.15 |
| Composition 1B | | | | | |
| Polishing | A (3 wt. %) | 0 | 0 | 300 | 4 |
| Composition 1C | | | | | |
| Polishing | A (3 wt. %) | 0 | 0 | 300 | 2.15 |
| Composition 1D | | | | | |
| Polishing | A (3 wt. %) | 0.12 | 0.24 | 300 | 2.15 |
| Composition 1E | | | | | |
| Polishing | A (2.1 wt. %) | 0.12 | 0.24 | 300 | 2.15 |
| Composition 1F | | | | | |
| Polishing | A (1.2 wt. %) | 0.12 | 0.24 | 300 | 2.15 |
| Composition 1G | | | | | |
| Polishing | A (3 wt. %) | 0 | 0.24 | 300 | 2.15 |
| Composition 1H | | | | | |

Patterned substrates comprising SOC or TEOS were polished under identical conditions using a Logitech benchtop polishing machine at 1 PSI (6.85 kPa) downforce using a NEXPLANAR™ E6088 pad commercially available from Entegris, Inc. (Aurora, IL) conditioned with a product commercially identified as A189L (3M, St. Paul, MN). Logitech polishing parameters were as follows: head speed=57 rpm, platen speed=63 rpm, total flow rate=50 mL/min. In this particular example, SOC patterned substrates were used as a surrogate for measuring the carbon removal rate of commercially available carbon film materials. Removal rates were calculated by measuring the film thickness, using spectroscopic elipsometry, and subtracting the final thickness from the initial thickness. Following polishing, the RR for SOC and TEOS were determined, and the results are set forth in Table 2.

TABLE 2
Polishing Removal Rates of Polishing Compositions 1A-1H

| Polishing | SOC RR | TEOS RR |
|---|---|---|
| Composition | (Å/min) | (Å/min) |
| Polishing | 79 | 24 |
| Composition 1A | | |
| Polishing | 311 | 46 |
| Composition 1B | | |
| Polishing | 0 | 7 |
| Composition 1C | | |
| Polishing | 6736 | 27 |
| Composition 1D | | |
| Polishing | 4894 | 102 |
| Composition 1E | | |
| Polishing | 5645 | 21 |
| Composition 1F | | |
| Polishing | 6346 | 84 |
| Composition 1G | | |
| Polishing | 7163 | 11 |
| Composition 1H | | |

As is apparent from the results set forth in Table 2, Polishing Compositions 1A and 1B, which contained an undoped silica particle, exhibited a low SOC removal rate compared to Polishing Composition 1D, which contained an aluminum-doped silica particle. These results show that the presence of aluminum ions (e.g., as aluminum doping on the silica particle) increased the selectivity for SOC removal relative to TEOS removal). Table 2 also shows that Polishing Composition 1C, which contained an aluminum-doped silica particle and had a pH of 4, exhibited no SOC removal, whereas Polishing Composition 1D, which contained an aluminum-doped silica particle and had a pH of 2.15, exhibited a high SOC removal rate. These results show that a higher pH (e.g., a pH of greater than 4) prohibits removal of SOC.

In addition, Table 2 shows that Polishing Compositions 1D-1H, which contained an aluminum-doped silica particle and had a pH of 2.15, exhibited a high SOC removal rate and selectivity for SOC removal relative to TEOS removal in all instances. Table 2 also shows that Compositions 1D-1H with and without iron cation all exhibited high SOC removal rates, demonstrating that iron is an optional additive.

### Example 2

This example demonstrates the preparation of polishing compositions comprising a silica abrasive and aluminum ions, a ligand, and a biocide according to the invention. Polishing Compositions 2A-2E were used, below, to demonstrate the beneficial polishing performance provided by a polishing composition prepared according to the invention.

For each of the compositions used in this example, silica Particle D (i.e., an aluminum-doped silica particle having an average particle size of 43 nm, a doping level of 0.05 wt. %, and a negative zeta potential of −29 mV at pH 2.5), silica Particle E (i.e., an aluminum-doped silica particle having an average particle size of 43 nm, a doping level of 0.2 wt. %, and a negative zeta potential of −29 mV at pH 2.5), silica Particle F (i.e., an aluminum-doped silica particle having an average particle size of 43 nm, a doping level of 0.2 wt. %, and a negative zeta potential of −22 mV at pH 2.5), silica Particle G (i.e., an aluminum-doped silica particle having an average particle size of 50 nm, a doping level of 0.1 wt. %, and a negative zeta potential of −21 mV at pH 2.5), and silica Particle H (i.e., an aluminum-doped silica particle having an average particle size of 62 nm, a doping level of 0.2 wt. %, and a negative zeta potential of −19 mV at pH 2.5), in the amounts set forth in Table 3, were combined with a ligand (i.e., malonic acid at 0.04 wt. %) and a biocide (i.e., 50 ppm of PROXEL™ AQ), and the pH of each polishing composition was adjusted to 2.7.

Patterned substrates comprising SOC or TEOS were polished under identical conditions using a Logitech benchtop polishing machine at 4 PSI (27.4 kPa) downforce using a NEXPLANAR™ E6088 pad commercially available from Entegris, Inc. (Aurora, IL) conditioned with a product commercially identified as SAESOL™ CLC-SI (SAESOL Diamond Ind. Co. Ltd.). Logitech polishing parameters were as follows: head speed=112 rpm, platen speed=115 rpm, total flow rate=66 mL/min. In this particular example, SOC patterned substrates were used as a surrogate for measuring the carbon removal rate of commercially available carbon film materials. Removal rates were calculated by measuring the film thickness, using spectroscopic elipsometry, and subtracting the final thickness from the initial thickness. Following polishing, the RR for SOC and TEOS were determined, and the results are set forth in Table 3.

TABLE 3
Polishing Compositions 2A-2E and Removal Rates

| | | Al-Doping | | |
|---|---|---|---|---|
| Polishing | Silica Abrasive | Level | SOC RR | TEOS RR |
| Composition | (wt. %) | (wt. %) | (Å/min) | (Å/min) |
| Polishing | D (0.5 wt. %) | 0.05 | 756 | 142 |
| Composition 2A | | | | |
| Polishing | E (0.5 wt. %) | 0.1 | 2170 | 82 |
| Composition 2B | | | | |
| Polishing | F (0.5 wt. %) | 0.2 | 2445 | 0 |
| Composition 2C | | | | |
| Polishing | G (0.5 wt. %) | 0.1 | 2548 | 115 |
| Composition 2D | | | | |
| Polishing | H (0.5 wt. %) | 0.2 | 3785 | 54 |
| Composition 2E | | | | |

As is apparent from the results set forth in Table 3, Polishing Compositions 2A-2E, which contained an aluminum-doped silica particle and had a pH of 2.7 at the point-of-use, exhibited a high SOC removal rate and selectivity for SOC removal relative to TEOS removal in all instances. In addition, Table 3 shows that increasing the level of doping of the aluminum-doped silica particle to 0.1 wt. % or higher significantly increased the selectivity for SOC removal relative to TEOS removal for both aluminum-doped silica particles.

### Example 3

This example demonstrates the preparation of polishing compositions comprising a silica abrasive and aluminum ions, and a biocide according to the invention. Polishing Compositions 3A, 3B, and 3C were used, below, to demonstrate the beneficial polishing performance provided by a polishing composition prepared according to the invention.

For each of the compositions used in this example, silica Particle I (i.e., an aluminum-doped silica particle having and average particle size of 67 nm, a doping level of 0.1 wt. %, and a negative zeta potential of −25 mV at pH 2.5), silica Particle J (i.e., an aluminum-doped silica particle having an average particle size of 99 nm, a doping level of 0.1 wt. %, and a negative zeta potential of −33 mV at pH 2.5), and silica Particle K (i.e., an aluminum-doped silica particle having an average particle size of 127 nm, a doping level of 0.1 wt. %, and a negative zeta potential of −32 mV at pH 2.5), in the amounts set forth in Table 4, were combined with a ligand (i.e., malonic acid at 0.24 wt. %) and a biocide (i.e., 300 ppm of PROXEL™ AQ), and the pH of each polishing composition was adjusted to 2.15. The final compositions were diluted six-fold (i.e., 6×) at the point-of-use (i.e., immediately prior to polishing), which resulted in a final pH of 2.7.

Patterned substrates comprising SOC or TEOS were polished under identical conditions using a Logitech benchtop polishing machine at 1 PSI (6.85 kPa) downforce using a NEXPLANAR™ E6088 pad commercially available from Entegris, Inc. (Aurora, IL) conditioned with a product commercially identified as A189L (3M, St. Paul, MN). Logitech polishing parameters were as follows: head speed=57 rpm, platen speed=63 rpm, total flow rate=50 mL/min. In this particular example, SOC patterned substrates were used as a surrogate for measuring the carbon removal rate of commercially available carbon film materials. Removal rates were calculated by measuring the film thickness, using spectroscopic elipsometry, and subtracting the final thickness from the initial thickness. Following polishing, the RR for SOC and TEOS were determined, and the results are set forth in Table 4.

TABLE 4
Polishing Compositions 3A-3C and Removal Rates

| | | Average | | |
|---|---|---|---|---|
| Polishing | Silica Abrasive | Particle | SOC RR | TEOS RR |
| Composition | (wt. %) | Size (nm) | (Å/min) | (Å/min) |
| Polishing | I (3 wt. %) | 67 | 3685 | 23 |
| Composition 3A | | | | |
| Polishing | J (3 wt. %) | 99 | 641 | 20 |
| Composition 3B | | | | |
| Polishing | K (3 wt. %) | 127 | 1938 | 38 |
| Composition 3C | | | | |

As is apparent from the results set forth in Table 4, Polishing Compositions 3A-3C, which contained an aluminum-doped silica particle, having a doping level of 0.1 wt. % and formulated at pH 2.15 with a pH of 2.7 at the point-of-use, exhibited a high SOC removal rate and selectivity for SOC removal relative to TEOS removal at all average particle sizes. Table 4 also shows that Polishing Composition 3A, having an average particle size of 67 nm, exhibited the highest SOC removal rate and selectivity for SOC removal relative to TEOS removal when compared to average particle sizes of 99 nm and 127 nm.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) a silica abrasive,
(b) aluminum ions, and
(c) water,
wherein (i) the aluminum ions are present in the polishing composition as an aluminum salt and/or (ii) the silica abrasive is doped with the aluminum ions, and wherein the polishing composition has a pH of about 1 to about 4.

2. The polishing composition of claim 1, wherein the polishing composition comprises about 0.001 wt. % to about 10 wt. % of the silica abrasive.

3. The polishing composition of claim 1, wherein the polishing composition comprises about 0.05 wt. % to about 5 wt. % of the silica abrasive.

4. The polishing composition of any one of claim 1, wherein the polishing composition has a pH of about 1 to about 3.

5. The polishing composition of claim 1, wherein the silica abrasive is colloidal silica, and wherein the colloidal silica has a surface area and the surface area has a surface hydroxyl group density of from about 1.5 hydroxyls per nm² to about 8 hydroxyls per nm².

6. The polishing composition of claim 1, wherein the silica abrasive has an average particle size of about 40 nm to about 150 nm.

7. The polishing composition of claim 1, wherein the silica abrasive has a negative zeta potential.

8. The polishing composition of claim 1, wherein the aluminum ions are present in the polishing composition as an aluminum salt, and wherein the aluminum salt is aluminum hydroxide, aluminum chloride, aluminum chlorohydrate, aluminum sulfate, alum, aluminum iodide, aluminum nitrate, aluminum phosphate, or a combination thereof.

9. The polishing composition of claim 1, wherein the silica abrasive is doped with the aluminum ions.

10. The polishing composition of claim 1, wherein the composition further comprises an iron cation, and wherein the iron cation is present in the polishing composition in an amount of about 1 ppm to about 1000 ppm based on the total weight of the polishing composition.

11. The polishing composition of claim 1, wherein the composition further comprises a ligand, and wherein the ligand is phosphoric acid, hydroxyethylidene diphosphonic acid, phthalic acid, isophthalic acid, terephthalic acid, citric acid, adipic acid, oxalic acid, malonic acid, fumaric acid, aspartic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, tartaric acid, a salt thereof, or a combination thereof.

12. The polishing composition of claim 11, wherein the iron cation and the ligand are present in the composition in a molar ratio of from 1:1 to 1:5.

13. The polishing composition of claim 1, wherein the composition further comprises a cationic polymer, and wherein the cationic polymer comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly[bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

14. The polishing composition of claim 1, wherein the polishing composition further comprises a nonionic polymer and the nonionic polymer is polyvinylpyrrolidone.

15. The polishing composition of claim 1, wherein the polishing composition further comprises an oxidizing agent.

16. A method of chemically-mechanically polishing a substrate comprising:
(i) providing a substrate,
(ii) providing a polishing pad,
(iii) providing a chemical-mechanical polishing composition comprising:
(a) about 0.001 wt. % to about 10 wt. % of a silica abrasive,
(b) aluminum ions, and
(c) water,
wherein (i) the aluminum ions are present in the polishing composition as an aluminum salt and/or (ii) the silica abrasive is doped with the aluminum ions, and wherein the polishing composition has a pH of about 1 to about 4,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

17. The method of claim 16, wherein the silica abrasive is colloidal silica, and wherein the colloidal silica has a surface area and the surface area has a surface hydroxyl group density of from about 1.5 hydroxyls per nm² to about 8 hydroxyls per nm².

18. The method of claim 16, wherein the aluminum ions are present in the polishing composition as an aluminum salt, and wherein the aluminum salt is aluminum hydroxide, aluminum chloride, aluminum chlorohydrate, aluminum sulfate, alum, aluminum iodide, aluminum nitrate, aluminum phosphate, or a combination thereof.

19. The method of claim 16, wherein the silica abrasive is doped with the aluminum ions.

20. The method of claim 16, wherein the composition further comprises a cationic polymer, and wherein the cationic polymer comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly[bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.
